(19) United States
(12) Patent Application Publication
(10) Pub. No.: US 2015/0171874 A1
(43) Pub. Date: Jun. 18, 2015

(54) PHASE LOCKED LOOP (PLL) APPARATUS AND OPERATING METHOD OF PLL APPARATUS

(71) Applicant: Electronics and Telecommunications Research Institute, Daejeon (KR)

(72) Inventor: Joon Gyu RYU, Daejeon (KR)

(21) Appl. No.: 14/561,011

(22) Filed: Dec. 4, 2014

(30) Foreign Application Priority Data
Dec. 13, 2013 (KR) 10-2013-0155536

(51) Int. Cl. H03L 7/099; H03L 7/087; H03L 7/093

(52) U.S. Cl. CPC H03L 7/099; H03L 7/093; H03L 7/087

(57) ABSTRACT

Provided are a phase locked loop (PLL) apparatus and an operating method of the PLL apparatus including a PLL unit to provide a fixed frequency signal, a converter to convert, using the fixed frequency signal, a frequency of a first signal oscillated by a first voltage-controlled oscillator (VCO) based on a first control voltage, a first frequency divider to divide the converted frequency of the first signal, and a first phase comparator to compare the divided frequency of the first signal to an input first reference frequency and detect a first phase difference, wherein the first VCO may adjust the first control voltage based on the detected first phase difference to equalize the divided frequency of the first signal to the first reference frequency.

### CROSS-REFERENCE TO RELATED APPLICATION

This application claims the benefit of Korean Patent Application No. 10-2013-0155536, filed on Dec. 13, 2013, in the Korean Intellectual Property Office, the disclosure of which is incorporated herein by reference.

### BACKGROUND

1. Field of the Invention

The present invention relates to a low-priced phase locked loop (PLL) apparatus with improved phase noise.

2. Description of the Related Art

Similar to a satellite communication system, a terminal may require a phase locked loop (PLL) apparatus capable of generating a local oscillation signal of a wide frequency band to transmit a signal at a predetermined frequency assigned from a central station in a wide frequency band.

The PLL apparatus may generate the local oscillation signal of the wide frequency band using a voltage-controlled oscillator (VCO).

FIG. 1 is a diagram illustrating a configuration of a general PLL apparatus.

Referring to FIG. 1, the general PLL apparatus may include a VCO, a frequency divider, a phase comparator, a charge pump, and a loop filter.

Phase noise of the PLL apparatus may be represented as shown in FIG. 2. The phase noise of the PLL apparatus may correspond to phase noise of a reference oscillator signal in a loop filter band, and may increase with a frequency division ratio. The phase noise of the PLL apparatus may be identical to phase noise of the VCO out of the loop filter band.

The PLL apparatus may decrease a frequency division ratio N to improve phase noise characteristics in the loop filter band, and may use the VCO with excellent phase noise characteristics out of the loop filter band.

To decrease the frequency division ratio N, an offset PLL as shown in FIG. 3 may be used. In the offset PLL, an output frequency of the VCO may be down-converted by a fixed PLL, divided by the frequency divider, and compared by the phase comparator.

The offset PLL may decrease a multiplied noise floor by decreasing the frequency division ratio N of the frequency divider. However, since phase noise of a fixed local oscillator (LO) in the offset PLL may be output within the loop filter band, an overall improvement of phase noise may be difficult. For such an improvement, in a general case, signals may be generated using an oscillator with excellent phase noise characteristics, multiplied, and used as the fixed LO. The oscillator with excellent phase noise characteristics may include, for example, a temperature compensated crystal oscillator (TCXO), and an oven controlled crystal oscillator.

Such a structure may have an excellent phase noise performance. However, due to use of a multiplier and a high-frequency oscillator, for example, the TCXO, relevant costs may increase.

### SUMMARY

An aspect of the present invention provides a phase locked loop (PLL) apparatus that may down-convert a frequency of a signal oscillated by a voltage-controlled oscillator (VCO) using a fixed frequency signal provided by a PLL unit, and provide the down-converted signal to a phase comparator, thereby decreasing an output frequency of the VCO, decreasing a frequency division ratio of a frequency divider having an effect on phase noise, and improving the phase noise.

Another aspect of the present invention also provides an effective improvement of overall phase noise of a PLL apparatus using a fixed frequency signal by maximizing a bandwidth associated with a loop filter in a PLL unit, minimizing a reference frequency of a phase comparator in the PLL unit, and improving the phase noise with respect to the fixed frequency signal provided by the PLL unit, without use of a multiplier and a high-priced oscillator, for example, a temperature compensated crystal oscillator (TCXO).

According to an aspect of the present invention, there is provided a PLL apparatus including a PLL unit to provide a fixed frequency signal, a converter to convert, using the fixed frequency signal, a frequency of a first signal oscillated by a first VCO based on a first control voltage, a first frequency divider to divide the converted frequency of the first signal, and a first phase comparator to compare the divided frequency of the first signal to an input first reference frequency and detect a first phase difference. The first VCO may adjust the first control voltage based on the detected first phase difference to equalize the divided frequency of the first signal to the first reference frequency.

According to another aspect of the present invention, there is also provided an operating method of a PLL apparatus, the method including providing a fixed frequency signal, by a PLL unit, converting, using the fixed frequency signal, a frequency of a first signal oscillated by a first VCO based on a first control voltage, by a converter, dividing the converted frequency of the first signal, by a first frequency divider, comparing the divided frequency of the first signal to an input first reference frequency and detecting a first phase difference, by a first phase comparator, and adjusting the first control voltage based on the detected first phase difference to equalize the divided frequency of the first signal to the first reference frequency, by the first VCO.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a diagram illustrating a configuration of a general phase locked loop (PLL) apparatus;

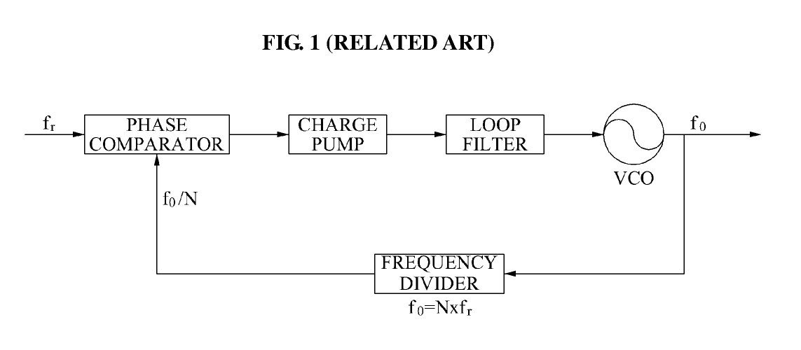

FIG. 2 is a graph illustrating phase noise characteristics of a general PLL apparatus;

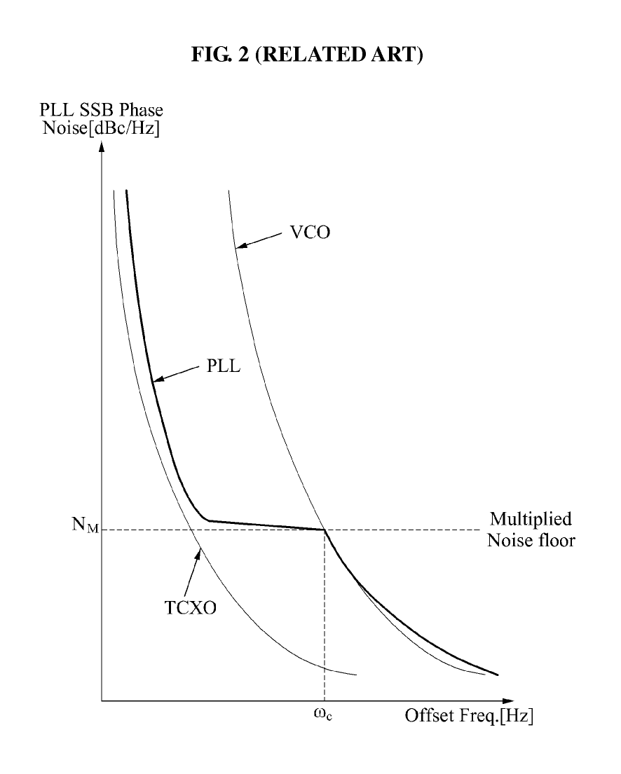

FIG. 3 is a diagram illustrating a configuration of a general offset PLL;

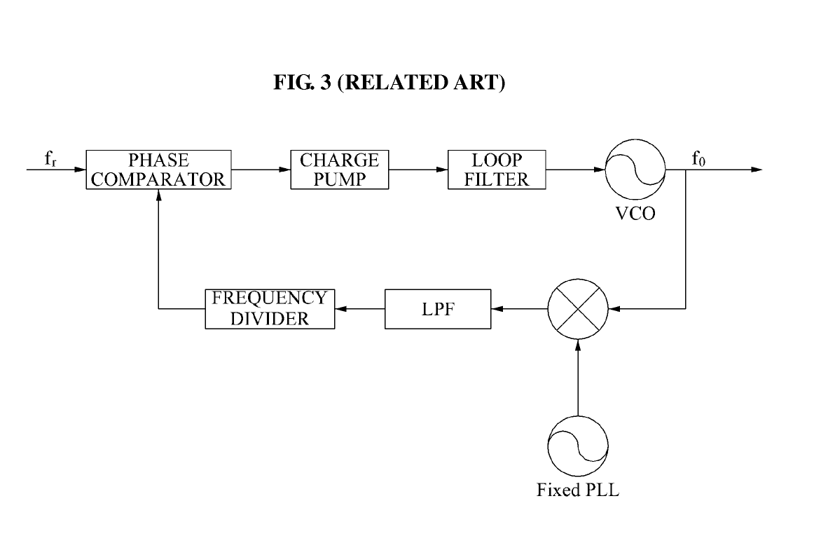

FIG. 4 is a diagram illustrating a configuration of a PLL apparatus according to an embodiment of the present invention;

FIG. 5 is a graph illustrating phase noise characteristics of a PLL apparatus according to an embodiment of the present invention; and

FIG. 6 is a flowchart illustrating an operating method of a PLL apparatus according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

Hereinafter, a phase locked loop (PLL) apparatus and an operating method of the PLL apparatus will be described in detail with reference to the accompanying drawings. Herein, the PLL apparatus may be provided in a form of an offset PLL.

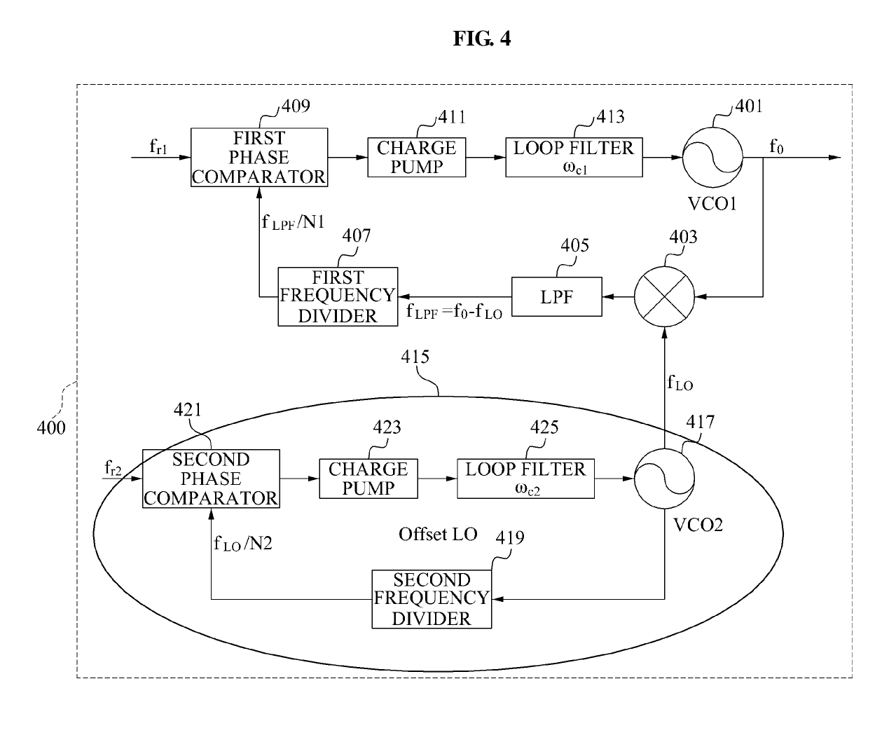

FIG. 4 is a diagram illustrating a configuration of a PLL apparatus 400 according to an embodiment of the present invention.

Referring to FIG. 4, the PLL apparatus 400 may include a first voltage-controlled oscillator (VCO) 401, a converter 403, a low-pass filter (LPF) 405, a first frequency divider 407, a first phase comparator 409, a charge pump 411, a loop filter 413, and a PLL unit 415.

The first VCO may oscillate a first signal of a corresponding frequency based on a first control voltage being applied. The first VCO 401 may adjust the first control voltage based on a first phase difference detected by the first phase comparator 409 to equalize a frequency of the first signal divided by the first frequency divider 407 to a first reference frequency input into the first phase comparator 409, thereby outputting the first signal of a frequency identical to the input first reference frequency.

The converter 403 may convert the frequency of the first signal oscillated by the first VCO 401 based on the first control voltage, using a fixed frequency signal provided by the

PLL unit 415. The converter 403 may include, for example, a mixer. The converter 403 may down-convert the frequency of the oscillated first signal by mixing the fixed frequency signal with the oscillated first signal.

The LPF 405 may allow a portion less than a frequency set for the first signal of which the frequency is converted by the converter 403 to pass, and block a portion greater than or equal to the set frequency.

The first frequency divider 407 may divide the converted frequency of the first signal passing through the LPF 405. The first frequency divider 407 may divide the frequency of the first signal based on a set first frequency division ratio. The first frequency divider 407 may receive the first signal of which the frequency is down-converted by the converter 403, and divide the frequency of the first signal based on a relatively low first frequency division ratio, when compared to a case in which a frequency of a first signal yet to be down-converted is divided, whereby improving phase noise.

The first phase comparator 409 may compare the divided frequency of the first signal to the input first reference frequency and detect the first phase difference.

The charge pump 411 may adjust an amount of current based on the first phase difference detected by the first phase comparator 409, and output a current signal adjusted based on the detected first phase difference.

The loop filter 413 may filter out a high-frequency component greater than or equal to a first bandwidth (pₐ set based a signal output from the charge pump 411.

The PLL unit 415 may provide the fixed frequency signal to the converter 403.

The PLL unit 415 may include a second VCO 417, a second frequency divider 419, a second phase comparator 421, a charge pump 423, and a loop filter 425.

The second VCO 417 may oscillate a second signal of a corresponding frequency based on a second control voltage being applied. The second VCO 417 may adjust the second control voltage based on a second phase difference detected by the second phase comparator 421 to equalize a frequency of the second signal divided by the second frequency divider 419 to a second reference frequency input into the second phase comparator 421, thereby outputting another second signal oscillated based on the adjusted second control voltage as the fixed frequency signal. The other second signal oscillated based on the adjusted second control voltage may correspond to a second signal of a frequency identical to the second reference frequency.

The second frequency divider 419 may divide the frequency of the second signal oscillated by the second VCO 417 based on the second control voltage. The second frequency divider 419 may divide the frequency of the second signal based on a set second frequency division ratio.

The second phase comparator 421 may compare the divided frequency of the second signal to the input second reference frequency and detect the second phase difference.

The charge pump 423 may adjust an amount of current based on the second phase difference detected by the second phase comparator 421, and output a current signal adjusted based on the detected second phase difference.

The loop filter 425 may filter out a high-frequency component greater than or equal to a second bandwidth (ω_{c2} set based a signal output from the charge pump 423. The second bandwidth associated with the loop filter 425 in the PLL unit 415 may be set to be maximized, for example, to be greater than the first bandwidth.

The phase noise of the PLL unit 415 in the PLL apparatus 400 may be expressed by Equation 1.

N_{M2}=1Hz noise floor+10 log(fᵣ₂)+20 log(N₂) [Equation 1]

In Equation 1, 1 Hz noise floor denotes unique noise of a PLL integrated circuit (IC) when a second frequency division ratio N₂ corresponds to “1” and a frequency of a phase comparator corresponds to 1 hertz (Hz). fᵣ₂ denotes a second reference frequency to be compared by the second phase comparator 421.

The phase noise of the PLL unit 415 may correspond to phase noise of a reference oscillator signal in a second loop filter band, for example, a second bandwidth. The reference oscillator signal may correspond to the second reference frequency, for example, a signal oscillated by a temperature compensated crystal oscillator (TCXO). The phase noise of the PLL unit 415 may increase with the second frequency division ratio N₂. Thus, to improve the phase noise performance of the PLL apparatus 400, the second bandwidth (ω_{c2} may be set to a maximized value. In addition, the second reference frequency may be set to a maximized value, and the second frequency division ratio N₂ may be set to a minimum value.

The phase noise of the PLL unit 415 may be identical to phase noise of the second VCO 417 out of a second loop filter band. However, when the second bandwidth ω₂ is greater than or equal to a preset value, the phase noise of the PLL unit 415 may not follow the phase noise of the second VCO 417.

A relationship between the first frequency division ratio N₁ associated with the first frequency divider 407 and the second frequency division ratio N₂ associated with the second frequency divider 419 in the PLL unit 415 may be expressed by Equation 2.

N₁=1−(N₂*fᵣ₂)/f_{O} [Equation 2]

In Equation 2, fᵣ₂ denotes a second reference frequency to be compared by the second phase comparator 421, and f_{O} denotes a signal output from the PLL apparatus 400.

Thus, the PLL apparatus 400 may enable a frequency of a signal f_{LO} output from the PLL unit 415 to be down-converted by the converter 403, divide the down-converted frequency of the signal by the first frequency division ratio N₁, and provide the signal to the first phase comparator 409, thereby improving phase noise efficiently.

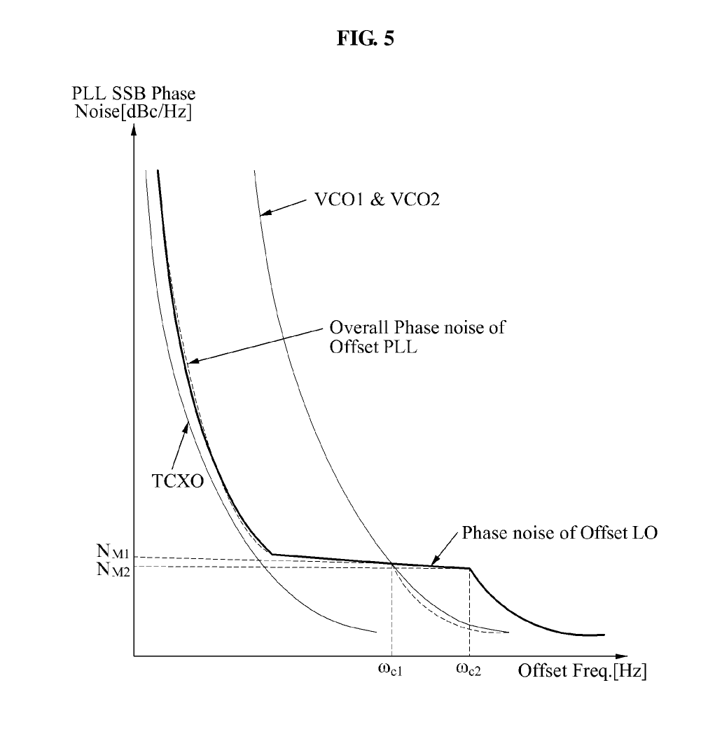

Referring to FIG. 5, the phase noise of the PLL unit 415 may be expressed by a first curve with respect to phase noise of an offset LO. In addition, the overall phase noise of the PLL apparatus 400 using the PLL unit 415 may be expressed by a second curve with respect to overall phase noise of an offset PLL.

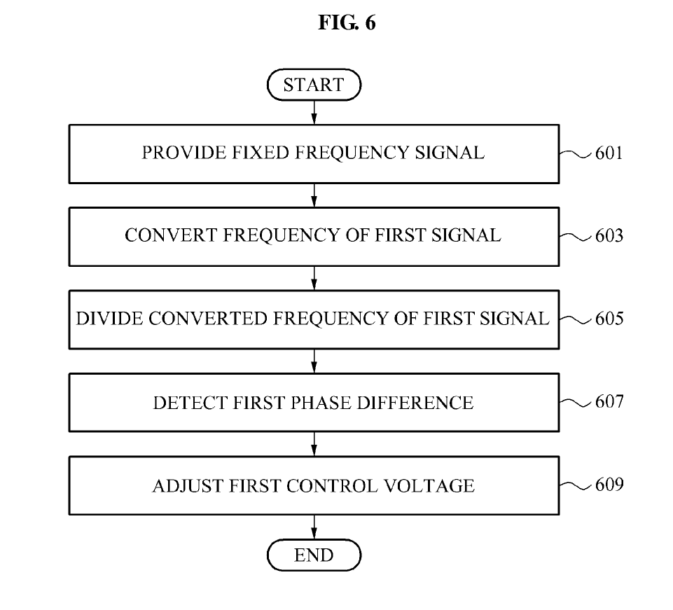

FIG. 6 is a flowchart illustrating an operating method of a PLL apparatus according to an embodiment of the present invention.

Referring to FIG. 6, in operation 601, the PLL apparatus may provide a fixed frequency signal.

The PLL apparatus may divide a frequency of a second signal oscillated by a second VCO based on a second control voltage. The PLL apparatus may compare the divided frequency of the second signal to an input second reference frequency and detect a second phase difference.

The PLL apparatus may filter out a high-frequency component greater than or equal to a second bandwidth set based on the detected second phase difference. The PLL apparatus may adjust the second control voltage based on the detected second phase difference to equalize the divided frequency of the second signal to the second reference frequency, and provide another second signal oscillated based on the adjusted second control voltage as the fixed frequency signal.

In operation 603, the PLL apparatus may convert, using the fixed frequency signal provided by a PLL unit, a frequency of a first signal oscillated by a first VCO based on a first control voltage. The PLL apparatus may down-convert the frequency of the oscillated first signal by mixing the fixed frequency signal with the oscillated first signal.

The PLL apparatus may allow a portion less than a frequency set for the frequency-converted first signal to pass, and block a portion greater than or equal to the set frequency.

In operation 605, the PLL apparatus may divide the converted frequency of the first signal. The PLL apparatus may divide the frequency of the first signal based on a set first frequency division ratio. The second frequency division ratio associated with a second frequency divider in the PLL unit may be lower than the first frequency division ratio.

In operation 607, the PLL apparatus may compare the divided frequency of the first signal to an input first reference frequency and detect a first phase difference. The PLL apparatus may filter out a high-frequency component greater than or equal to a first bandwidth set based on the detected first phase difference. The second bandwidth associated with a loop filter in the PLL unit may be greater than the first bandwidth.

In operation 609, the PLL apparatus may adjust the first control voltage based on the detected first phase difference to equalize the divided frequency of the first signal to the first reference frequency. According to an embodiment of the present invention, it is possible to provide a PLL apparatus that may down-convert a frequency of a signal oscillated by a VCO using a fixed frequency signal provided by a PLL unit, and provide the down-converted signal to a phase comparator, thereby decreasing an output frequency of the VCO, decreasing a frequency division ratio of a frequency divider having an effect on phase noise, and improving the phase noise.

According to an embodiment of the present invention, it is possible to effectively improve overall phase noise of a PLL apparatus using a fixed frequency signal by maximizing a bandwidth associated with a loop filter in a PLL unit, minimizing a reference frequency of a phase comparator in the PLL unit, and improving the phase noise with respect to the fixed frequency signal provided by the PLL unit, without use of a multiplier and a high-priced oscillator, for example, a TCXO.

The units described herein may be implemented using hardware components and software components. For example, the hardware components may include microphones, amplifiers, band-pass filters, audio to digital convertors, and processing devices. A processing device may be implemented using one or more general-purpose or special purpose computers, such as, for example, a processor, a controller and an arithmetic logic unit, a digital signal processor, a microcomputer, a field programmable array, a programmable logic unit, a microprocessor or any other device capable of responding to and executing instructions in a defined manner. The processing device may run an operating system (OS) and one or more software applications that run on the OS. The processing device also may to access, store, manipulate, process, and create data in response to execution of the software.

For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such a parallel processors.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums. The non-transitory computer readable recording medium may include any data storage device that can store data which can be thereafter read by a computer system or processing device. Examples of the non-transitory computer readable recording medium include read-only memory (ROM), random-access memory (RAM), CD-ROMs, magnetic tapes, floppy disks, optical data storage devices. Also, functional programs, codes, and code segments that accomplish the examples disclosed herein can be easily construed by programmers skilled in the art to which the examples pertain based on and using the flow diagrams and block diagrams of the figures and their corresponding descriptions as provided herein.

The method according to the above-described exemplary embodiments of the present invention may be recorded in computer-readable media including program instructions to implement various operations embodied by a computer. The media may also include, alone or in combination with the program instructions, data files, data structures, and the like.

Examples of computer-readable media include magnetic media such as hard disks, floppy disks, and magnetic tape; optical media such as CD ROM disks and DVDs; magneto-optical media such as floptical disks; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described exemplary embodiments of the present invention, or vice versa.

A number of examples have been described above. Nevertheless, it should be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A phase locked loop (PLL) apparatus comprising:
a PLL unit to provide a fixed frequency signal;
a converter to convert, using the fixed frequency signal, a frequency of a first signal oscillated by a first voltage-controlled oscillator (VCO) based on a first control voltage;
a first frequency divider to divide the converted frequency of the first signal; and
a first phase comparator to compare the divided frequency of the first signal to an input first reference frequency and detect a first phase difference,
wherein the first VCO adjusts the first control voltage based on the detected first phase difference to equalize the divided frequency of the first signal to the first reference frequency.

2. The apparatus of claim 1, wherein the PLL unit comprises:
a second frequency divider to divide a frequency of a second signal oscillated by a second VCO based on a second control voltage; and
a second phase comparator to compare the divided frequency of the second signal to an input second reference frequency and detect a second phase difference, and
the second VCO adjusts the second control voltage based on the detected second phase difference to equalize the divided frequency of the second signal to the second reference frequency, and provides another second signal oscillated based on the adjusted control voltage as the fixed frequency signal.

3. The apparatus of claim 2, wherein the PLL unit further comprises:
a loop filter to filter out a high-frequency component greater than or equal to a second bandwidth set based on the detected second phase difference.

4. The apparatus of claim 1, wherein the converter down-converts the frequency of the oscillated first signal by mixing the fixed frequency signal with the oscillated first signal.

5. The apparatus of claim 1, further comprising:
a loop filter to filter out a high-frequency component greater than or equal to a first bandwidth set based on the detected first phase difference.

6. The apparatus of claim 5, wherein a second bandwidth associated with a loop filter in the PLL unit is greater than the first bandwidth.

7. The apparatus of claim 1, further comprising:
a low-pass filter (LPF) to allow a portion less than a frequency set for the frequency-converted first signal to pass, and block a portion greater than or equal to the set frequency.

8. The apparatus of claim 1, wherein the first frequency divider divides the frequency of the first signal based on a set first frequency division ratio, and a second frequency division ratio associated with a second frequency divider in the PLL unit is lower than the first frequency division ratio.

9. An operating method of a phase locked loop (PLL) apparatus, the method comprising:
providing a fixed frequency signal, by a PLL unit;
converting, using the fixed frequency signal, a frequency of a first signal oscillated by a first voltage-controlled oscillator (VCO) based on a first control voltage, by a converter;
dividing the converted frequency of the first signal, by a first frequency divider;
comparing the divided frequency of the first signal to an input first reference frequency and detecting a first phase difference, by a first phase comparator; and
adjusting the first control voltage based on the detected first phase difference to equalize the divided frequency of the first signal to the first reference frequency, by the first VCO.

10. The method of claim 9, further comprising:
dividing a frequency of a second signal oscillated by a second VCO based on a second control voltage, by a second frequency divider in the PLL unit;
comparing the divided frequency of the second signal to an input second reference frequency and detecting a second phase difference, by a second phase comparator in the PLL unit; and
adjusting the second control voltage based on the detected second phase difference to equalize the divided frequency of the second signal to the second reference frequency, and providing another second signal oscillated based on the adjusted control voltage as the fixed frequency signal, by the second VCO in the PLL unit.

11. The method of claim 10, further comprising:
filtering out a high-frequency component greater than or equal to a second bandwidth set based on the detected second phase difference, by a loop filter in the PLL unit.

12. The method of claim 9, wherein the converting comprises down-converting the frequency of the oscillated first signal by mixing the fixed frequency signal with the oscillated first signal, by the converter.

13. The method of claim 9, further comprising:
filtering out a high-frequency component greater than or equal to a first bandwidth set based on the detected first phase difference, by a loop filter.

14. The method of claim 13, wherein a second bandwidth associated with a loop filter in the PLL unit is greater than the first bandwidth.

15. The method of claim 9, further comprising:
allowing a portion less than a frequency set for the frequency-converted first signal to pass, and blocking a portion greater than or equal to the set frequency, by a low-pass filter (LPF).

16. The method of claim 9, wherein the dividing of the converted frequency of the first signal comprises dividing the frequency of the first signal based on a set first frequency division ratio, by the first frequency divider, and
a second frequency division ratio associated with a second frequency divider in the PLL unit is lower than the first frequency division ratio.
